(19) United States
(12) Patent Application Publication
(10) Pub. No.: US 2024/0321688 A1
(43) Pub. Date: Sep. 26, 2024

(54) SEMICONDUCTOR DEVICE AND METHOD OF MANUFACTURING THE SAME

(71) Applicant: SAMSUNG ELECTRONICS CO., LTD, Suwon-si (KR)

(72) Inventor: SUNGMIN KIM, Suwon-si (KR)

(21) Appl. No.: 18/393,837

(22) Filed: Dec. 22, 2023

(30) Foreign Application Priority Data
Mar. 24, 2023 (KR) 10-2023-0039192
Jun. 8, 2023 (KR) 10-2023-0073739

(51) Int. Cl. H01L 23/48; H01L 29/06; H01L 29/417; H01L 29/423; H01L 29/775; H01L 29/786

(52) U.S. Cl. CPC H01L 23/481; H01L 29/0673; H01L 29/41733; H01L 29/42392; H01L 29/775; H01L 29/78696

(57) ABSTRACT

A semiconductor device includes a front-side wiring structure connected to a signal line, a back-side wiring structure arranged below the front-side wiring structure and connected to a power line, and an electronic element between the front-side wiring structure and the back-side wiring structure, wherein the electronic element includes a plurality of gate structures, each of the plurality of gate structures includes a gate electrode, a capping film, and a gate spacer, and the capping film includes a first capping film and a second capping film, the first capping film being on a bottom surface of the gate electrode, and the second capping film being on a top surface of the gate electrode.

### CROSS-REFERENCE TO RELATED APPLICATIONS

This application is based on and claims priority under 35 U.S.C. § 119 to Korean Patent Application Nos. 10-2023-0039192, filed on Mar. 24, 2023, and 10-2023-0073739, filed on Jun. 8, 2023, in the Korean Intellectual Property Office, the disclosures of which are incorporated by reference herein in their entireties.

### BACKGROUND

### 1. Field

Embodiments relate to a semiconductor device and a method of manufacturing the same.

### 2. Description of the Related Art

With the rapid development of the electronics industry and users' needs, electronic equipment is becoming lighter and more compact. Accordingly, semiconductor memory devices used in electronic equipment are required to have a high integration density, and thus, the design rules for the components of semiconductor memory devices have been reduced. Therefore, it is difficult to secure the reliability of semiconductor memory devices.

### SUMMARY

According to an aspect of embodiments, there is provided a semiconductor device including a front-side wiring structure connected to a signal line, a back-side wiring structure arranged below the front-side wiring structure and connected to a power line, and an electronic element between the front-side wiring structure and the back-side wiring structure, wherein the electronic element includes a plurality of gate structures, each of the plurality of gate structures includes a gate electrode, a capping film, and a gate spacer, and the capping film includes a first capping film and a second capping film, the first capping film being on a bottom surface of the gate electrode, and the second capping film being on a top surface of the gate electrode.

According to another aspect of embodiments, there is provided a semiconductor device including a front-side wiring structure connected to a signal line, a back-side wiring structure arranged below the front-side wiring structure and connected to a power line, and an electronic element between the front-side wiring structure and the back-side wiring structure, wherein the electronic element includes a plurality of gate structures separated from each other in a first horizontal direction and a source/drain region between the plurality of gate structures, each of the plurality of gate structures includes a gate electrode, a capping film, and a gate spacer, and the capping film includes a first capping film and a second capping film, the first capping film being on a bottom surface of the gate electrode, and the second capping film being on a top surface of the gate electrode.

According to a further aspect of embodiments, there is provided a semiconductor device including a front-side wiring structure connected to a signal line, a back-side wiring structure arranged below the front-side wiring structure and connected to a power line, an electronic element between the front-side wiring structure and the back-side wiring structure, a first insulating layer filling a space between the back-side wiring structure and the electronic element, and a second insulating layer filling a space between the front-side wiring structure and the electronic element, wherein the electronic element includes a plurality of gate structures separated from each other in a first horizontal direction and a source/drain region between the plurality of gate structures, the source/drain region includes a top surface facing the front-side wiring structure and a bottom surface facing the back-side wiring structure, the top surface of the source/drain region is round toward the front-side wiring structure, the bottom surface of the source/drain region is flat, and each of the plurality of gate structures includes a gate electrode, a capping film, and a gate spacer, wherein the capping film includes a first capping film and a second capping film, the first capping film being on a bottom surface of the gate electrode, and the second capping film being on a top surface of the gate electrode, and the gate spacer covers a sidewall of each of the gate electrode, the first capping film, and the second capping film.

### BRIEF DESCRIPTION OF THE DRAWINGS

Features will become apparent to those of skill in the art by describing in detail exemplary embodiments with reference to the attached drawings, in which:

FIGS. 1A and 1B are diagrams illustrating semiconductor devices according to embodiments;

FIG. 2 is a cross-sectional view of a semiconductor device according to an embodiment;

FIGS. 3A to 3J are diagrams of stages in a method of manufacturing a semiconductor device, according to an embodiment;

FIG. 4 is a block diagram of a system-on-chip (SoC) according to an embodiment; and

FIG. 5 is a block diagram of a computing system including a memory storing a program, according to an embodiment.

### DETAILED DESCRIPTION

Hereinafter, embodiments are described in detail with reference to the accompanying drawings. In the drawings, like numerals denote like elements and redundant descriptions thereof will be omitted.

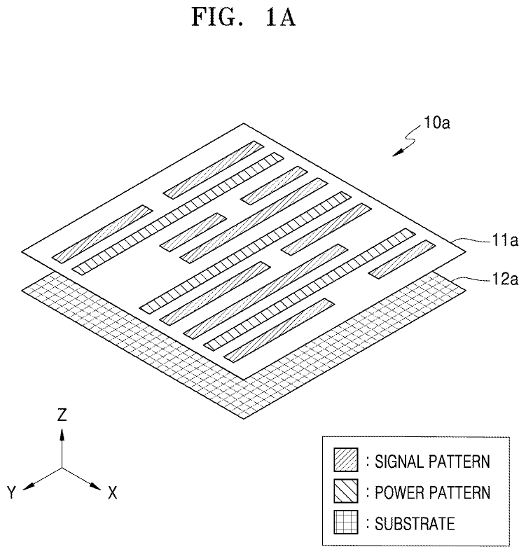

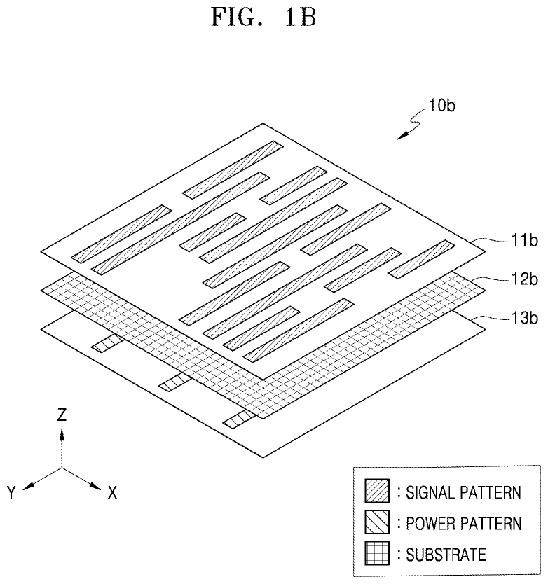

FIGS. 1A and 1B are diagrams illustrating semiconductor devices according to embodiments. Hereinafter, redundant descriptions of FIGS. 1A and 1B are omitted.

Although a logic device is illustrated as an example of a semiconductor device in the drawings, this is just an example. Other examples of a semiconductor device may include a system large scale integration (LSI), a flash memory, a dynamic random access memory (DRAM), a static RAM (SRAM), an electrically erasable programmable ROM (EEPROM), a phase-change RAM (PRAM), a magnetic RAM (MRAM), a resistive RAM (RRAM), an image sensor, e.g., a complementary metal-oxide semiconductor (CMOS) image sensor (CIS), a micro-electro-mechanical system (MEMS), an active device, a passive device, and the like.

Herein, an X-axis direction and a Y-axis direction may be respectively referred to as a first horizontal direction and a second horizontal direction, and a Z-axis direction may be referred to as a vertical direction. A plane defined by the X-axis and the Y-axis may be referred to as a horizontal plane. An element positioned in a +Z direction compared to another element may be considered as being above the other element. An element positioned in a −Z direction compared to another element may be considered as being below the other element. The area of an element may refer to a size occupied by the element in a plane parallel with the horizontal plane, and the width of the element may refer to a length of the element in a direction that is perpendicular to a direction in which the element extends. A surface exposed in the ±Z direction may be referred to as a top surface, a surface exposed in the −Z direction may be referred to as a bottom surface, and a surface exposed in a ±X direction or a ±Y direction may be referred to as a side surface. In the accompanying drawings, only some layers may be illustrated for convenience, and a via connecting an upper pattern to a lower pattern may be illustrated even though the via is below the upper pattern to show the connection between the upper pattern and the lower pattern. A pattern, e.g., a pattern of a wiring layer constituted of a conductive material, may be referred to as a conductive pattern or simply a pattern.

Referring to FIG. 1A, a semiconductor device 10a may include a wiring layer 11a and a substrate 12a. Elements (e.g., transistors) may be formed on the substrate 12a. The wiring layer 11a may be above the elements. Patterns including a conductive material may be formed in the wiring layer 11a. For example, as shown in FIG. 1A, signal patterns for input signals and/or output signals of elements may be formed in the wiring layer 11a and power patterns for supplying power to elements may be formed in the wiring layer 11a.

In some embodiments, patterns (i.e., signal and power patterns) formed in the wiring layer 11a may include metal, and the wiring layer 11a may be referred to as a metal layer. The semiconductor device 10a may include a plurality of wiring layers. Patterns respectively formed in adjacent wiring layers may be electrically connected to each other through a via. For example, the semiconductor device 10a may include at least one wiring layer between the wiring layer 11a and the substrate 12a and at least one wiring layer above the wiring layer 11a.

Supply voltage, e.g., positive supply voltage and/or negative supply voltage (or ground potential), may be applied to power patterns. For example, elements may receive a supply voltage, which is applied to pads respectively on a plurality of wiring layers, through patterns respectively formed on the wiring layers. As such, a structure in which a supply voltage is provided from above the substrate 12a may be referred to as a front-side power delivery network (FSPDN). In some embodiments, power patterns may be regularly arranged in the wiring layer 11a such that power is reliably supplied to elements, and signals patterns may be arranged in a region of the wiring layer 11a, in which the power patterns are not arranged. For example, as shown in FIG. 1A, power patterns may extend in the Y-axis direction in the wiring layer 11a to be parallel with each other at regular intervals and signals patterns may extend in the Y-axis direction in the wiring layer 11a to be arranged between the power patterns.

With the development of semiconductor processes, the size of elements formed on the substrate 12a may decrease. Accordingly, it may not be easy to form signals patterns for routing input signals and output signals of the elements and power patterns may increase routing congestion.

Referring to FIG. 1B, a semiconductor device 10b may include a wiring layer 11b, a substrate 12b, and a back-side wiring layer 13b. Elements (e.g., transistors) may be formed on the substrate 12b. The wiring layer 11b may be above the elements and the back-side wiring layer 13b may be below the substrate 12b. The wiring layer 11b may be referred to as a front-side wiring layer to be distinguished from the back-side wiring layer 13b. As shown in FIG. 1B, signal patterns may be formed in the wiring layer 11b and power patterns may be formed in the back-side wiring layer 13b. Power patterns may be omitted from the wiring layer 11b and signals patterns may be arranged in a region of the wiring layer 11b, from which the power patterns are omitted. Accordingly, the semiconductor device 10b of FIG. 1B may provide a higher routability than the semiconductor device 10a of FIG. 1A.

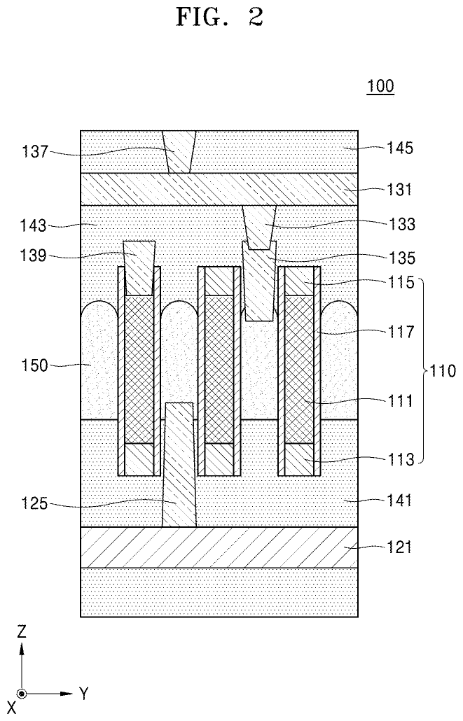

To provide power from the power patterns of the back-side wiring layer 13b to elements, the semiconductor device 10b may further include a through-silicon via (TSV). As described below with reference to FIG. 2, the TSV may be connected to the back-side wiring layer 13b and to a pattern formed in a wiring layer between the wiring layer 11b and the substrate 12b. Accordingly, a supply voltage may be provided from the power pattern of the back-side wiring layer 13b to the elements through the TSV. As such, a structure in which a supply voltage is provided from below the substrate 12b may be referred to as a back-side power delivery network (BSPDN). Herein, a power pattern formed in the back-side wiring layer 13b may be referred to as a power line.

In some embodiments, a TSV may be connected to a pattern in a first wiring layer closest to the substrate 12b. Patterns in the first wiring layer may have a higher resistance than patterns in other wiring layers, and accordingly, an element remote from the TSV may receive a decreased positive supply voltage and/or an increased negative supply voltage.

As described below with reference to the accompanying drawings, the semiconductor device 10b may further include contacts, which are arranged for reliable power supply to elements, and accordingly, the performance and reliability of the semiconductor device 10b may increase. An additional area for arranging contacts may not be omitted and the increase in the area of the semiconductor device 10b may be limited. Routing resources may increase in front-side wiring layers including the wiring layer 11b because of power patterns arranged in the back-side wiring layer 13b, and accordingly, routing congestion may be eliminated from the semiconductor device 10b.

FIG. 2 is a cross-sectional view of a semiconductor device 100 according to an embodiment. FIGS. 1A and 1B are also referred to in the description below and redundant descriptions made above with reference to FIGS. 1A and 1B are briefly given or omitted.

Referring to FIG. 2, the semiconductor device 100 may include an electronic element, a front-side wiring structure, and a back-side wiring structure. Here, the front-side wiring structure may correspond to the wiring layer 11b in FIG. 1B and the back-side wiring structure may correspond to the back-side wiring layer 13b in FIG. 1B. Each of the front-side wiring structure and the back-side wiring structure may be connected to the electronic element.

The semiconductor device 100 may include a plurality of electronic elements. Each electronic element may be configured as a fin field-effect transistor (finFET) including a channel region in fin-type pattern, but it is just an example. In embodiments, the electronic element may include a tunneling FET, a transistor including a nanowire, a transistor including nanosheet, a vertical FET (VFET), a complementary FET (CFET), or a three-dimensional (3D) transistor. Alternatively, a first electronic element and a second electronic element may respectively include a bipolar junction transistor and a laterally-diffused metal-oxide semiconductor (LDMOS) transistor.

The electronic element may include a plurality of gate structures 110 and a source/drain region 150. The gate structures 110 may be spaced apart from each other in the first horizontal direction. Each of the gate structures 110 may include a gate electrode 111, a capping film, and a gate spacer 117. The capping film may include a first capping film 113 and a second capping film 115.

The gate electrode 111 may include, e.g., metal, metal nitride, metal carbide, or a combination thereof. The metal may be selected from among, e.g., Ti, W, Ru, Nb, Mo, Hf, Ni, Co, Pt, Yb, Tb, Dy, Er, and Pd. The metal nitride may be selected from among, e.g., TiN and TaN. The metal carbide may include, e.g., TiAlC. According to the configuration of the semiconductor device 100, a plurality of gate electrodes 111 may be separated from each other by an isolator between at least some adjacent transistors. The gate electrodes 111 may include different materials from each other according to transistor regions.

The first capping film 113 and the second capping film 115 may cover one of the gate electrodes 111, e.g., each of the gate electrodes 111 may be between the first capping film 113 and the second capping film 115 in the vertical direction (e.g., along the Z-axis direction). In detail, the first capping film 113 may cover the bottom surface of the gate electrode 111. The second capping film 115 may cover the top surface of the gate electrode 111. The bottom surface of the gate electrode 111 may face the back-side wiring structure and the top surface of the gate electrode 111 may face the front-side wiring structure.

The first capping film 113 and the second capping film 115 may be separated from each other by the gate electrode 111 in the vertical direction. The first capping film 113 may include the same material as the second capping film 115. In embodiments, the first capping film 113 and the second capping film 115 may include at least one material of, e.g., oxide, nitride, and silicon nitride. In embodiments, the thickness of the first capping film 113 in the vertical direction may be greater than or equal to the thickness of the second capping film 115 in the vertical direction.

In embodiments, one of the gate structures 110 may not include the second capping film 115. The top surface of the gate electrode 111 of the gate structure that does not include the second capping film 115 may be in contact (e.g., direct contact) with a gate contact 139. The gate electrode 111 may be supplied with power through the gate contact 139.

The gate spacer 117 may be on each of opposite sidewalls of the gate electrode 111. The gate spacer 117 may insulate the source/drain region 150 from the gate electrode 111. The gate spacer 117 may extend in the vertical direction along a side surface or sidewall of the gate electrode 111. The gate spacer 117 may conformally cover the gate electrode 111, the first capping film 113, and the second capping film 115. For example, the gate spacer 117 may continuously extend along entire lateral surfaces of the gate electrode 111, the first capping film 113, and the second capping film 115, such that the gate spacer 117 may completely separate between each of the gate electrodes 111 and an adjacent source/drain region 150. The gate spacer 117 may include multiple layers, according to embodiments. The gate spacer 117 may include, e.g., oxide, nitride, and oxynitride.

The source/drain region 150 may be in an active region. The source/drain region 150 may be in a recess formed in an upper portion of the active region, but whether to form a recess or the depth of a recess may vary with embodiments. The source/drain region 150 may be configured as a semiconductor layer including silicon and may be formed epitaxially.

In embodiments, a plurality of source/drain regions 150 may include a first source/drain region in a first active region and a second source/drain region in a second active region. The first and second source/drain regions may include different types and/or concentrations of impurities from each other. For example, the first source/drain region may have a second conductivity and the second source/drain region may have a first conductivity.

In embodiments, each of the source/drain regions 150 may include a top surface facing the front-side wiring structure and a bottom surface facing the back-side wiring structure. The top surface of each source/drain region 150 may have a round shape having a width decreasing toward the front-side wiring structure. The bottom surface of the source/drain region 150 may have a flat shape.

The semiconductor device 100 may further include a first insulating layer 141, a second insulating layer 143, and a front-side wiring insulating film 145. The first insulating layer 141 and the second insulating layer 143 may be between the front-side wiring structure and the back-side wiring structure. The first insulating layer 141 and the second insulating layer 143 may cover the source/drain regions 150 and the gate structures 110. For example, the first insulating layer 141 and the second insulating layer 143 may include at least one of oxide, nitride, and oxynitride, and may include a low-k dielectric material.

The front-side wiring structure may be formed and/or arranged on the top surface of the second insulating layer 143. The front-side wiring structure may provide a signal line 131 for various electronic elements (e.g., transistors) formed between the front-side wiring structure and the back-side wiring structure. The front-side wiring structure may include the front-side wiring insulating film 145. The front-side wiring insulating film 145 may include multiple layers, which may be sequentially stacked above the second insulating layer 143. The front-side wiring insulating film 145 may include front-side wiring patterns and front-side via patterns therein. The front-side wiring insulating film 145 may insulate the front-side wiring patterns from the front-side via patterns.

In embodiments, the front-side wiring structure may be connected to an electronic element. For example, the front-side wiring structure may be connected to the source/drain region 150 through a front-side contact 135 thereof and a front-side via 133 thereof. The front-side contact 135 and the front-side via 133 may pass through the second insulating layer 143 and have a tapered shape having a decreasing width toward the source/drain region 150. The front-side contact 135 and the front-side via 133 may apply an electrical signal to the source/drain region 150. The front-side contact 135 may be in contact (e.g., direct contact) with or may partially pass through the top surface of the source/drain region 150.

The back-side wiring structure may be formed and/or arranged on the bottom surface of the first insulating layer 141. The back-side wiring structure may provide a power line 121 for various electronic elements formed between the front-side wiring structure and the back-side wiring structure. In embodiments, the back-side wiring structure may provide the power line 121 and a signal line for electronic elements. The back-side wiring structure may include a back-side wiring insulating film. The back-side wiring insulating film may include multiple layers, which may be sequentially stacked below the first insulating layer 141. The back-side wiring insulating film may include back-side wiring patterns and back-side via patterns therein. The back-side wiring insulating film may insulate the back-side wiring patterns from the back-side via patterns.

According to embodiments, the back-side wiring structure may be connected to an electronic element. For example, the back-side wiring structure may be connected to the source/drain region 150 through a back-side contact 125 thereof. The back-side contact 125 may pass through the first insulating layer 141 and have a tapered shape having a decreasing width toward the source/drain region 150. The back-side contact 125 may apply power or an electrical signal to the source/drain region 150. The back-side contact 125 may be in contact with or may partially pass through the bottom surface of the source/drain region 150.

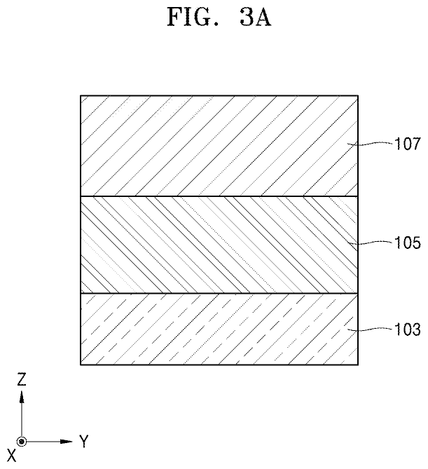

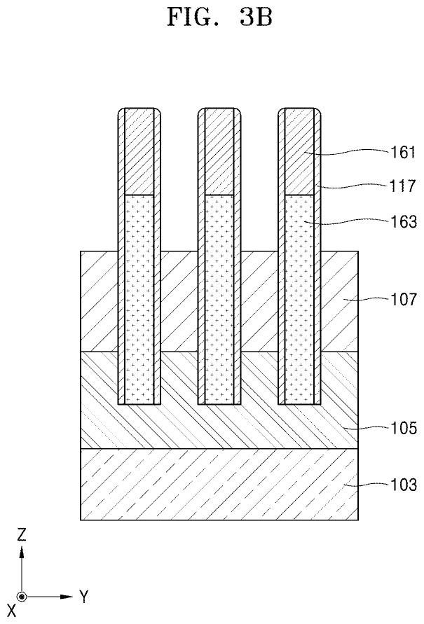

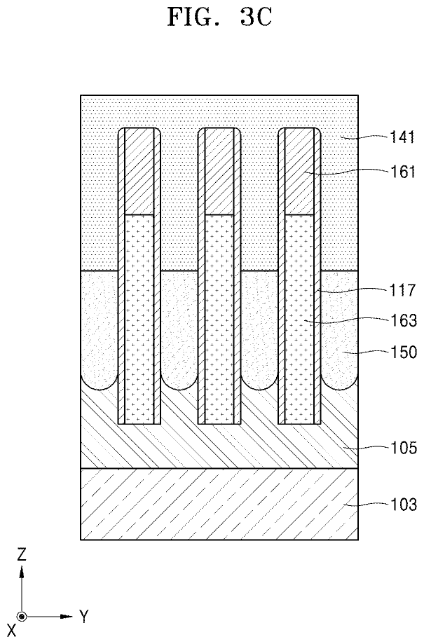

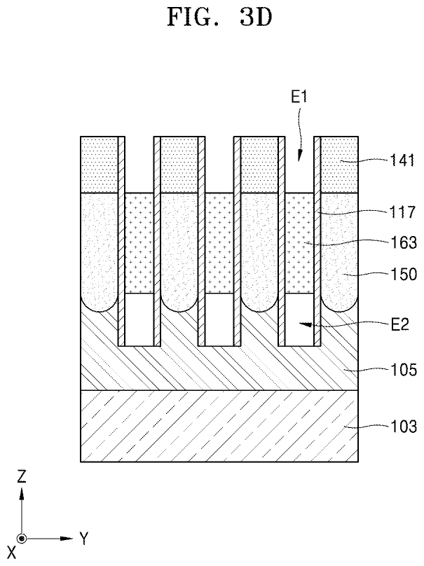

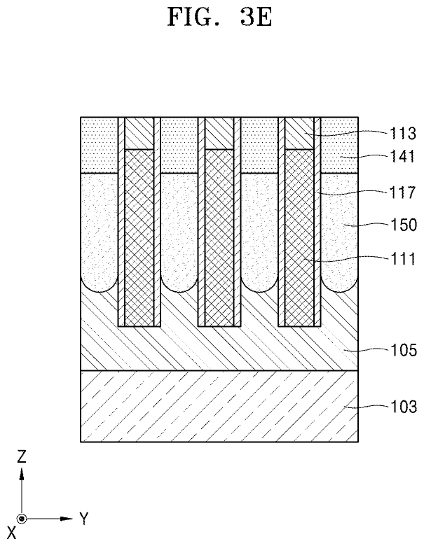

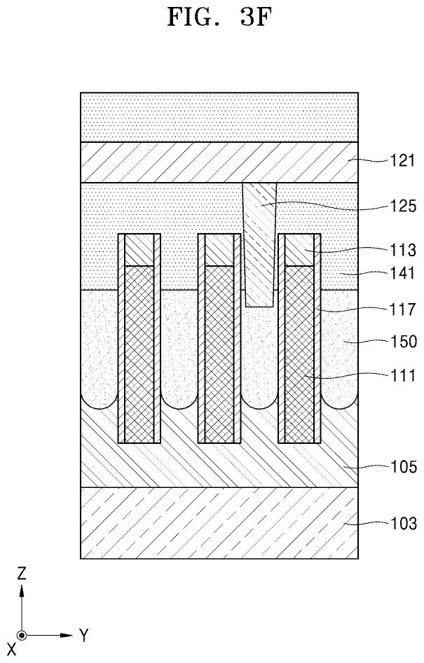

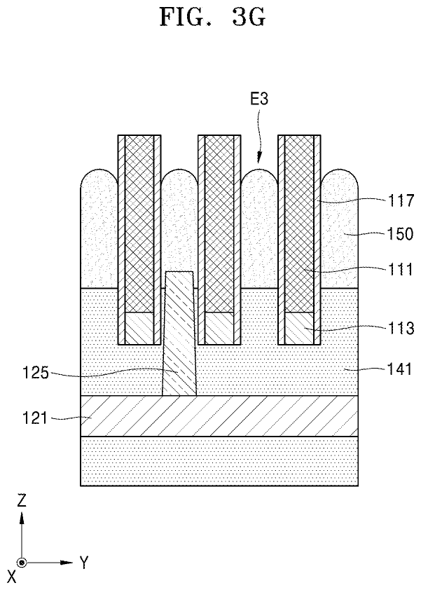

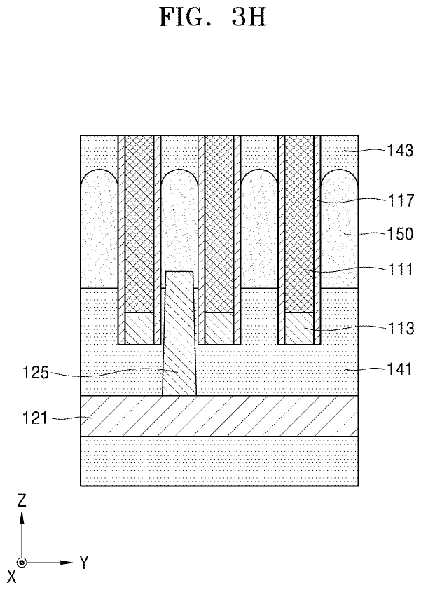

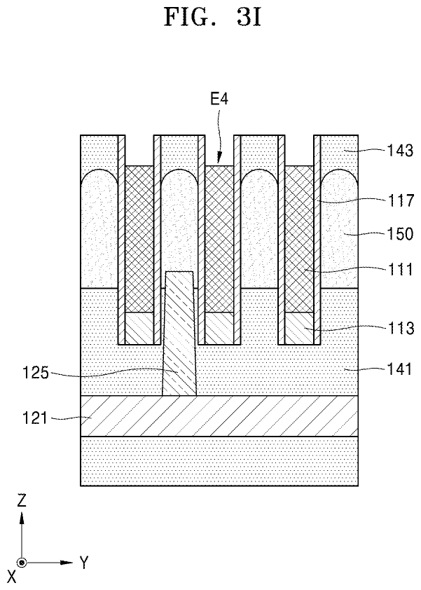

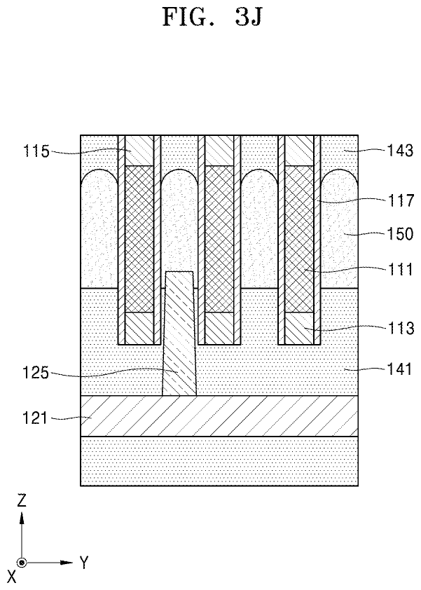

FIGS. 3A to 3J are diagrams illustrating stages in a method of manufacturing a semiconductor device, according to an embodiment.

Referring to FIGS. 3A and 3B, a first sacrificial layer 103, a second sacrificial layer 105, and a third sacrificial layer 107 may be sequentially stacked. Each of the first sacrificial layer 103 and the third sacrificial layer 107 may be configured as a silicon layer and the second sacrificial layer 105 may be configured as a SiGe layer.

Subsequently, an isolation film may be formed, and then a fourth sacrificial layer may be stacked on the third sacrificial layer 107. After the fourth sacrificial layer is formed, a trench may be formed in the second sacrificial layer 105 and the third sacrificial layer 107, and a dummy gate structure may be formed in the trench. The dummy gate structure may include a dummy capping film 161, a dummy gate 163, and the gate spacer 117. The gate spacer 117, the dummy gate 163, and the dummy capping film 161 may be sequentially formed in the trench formed in the second sacrificial layer 105 and the third sacrificial layer 107. After the dummy gate structure is formed, etching may be performed on the dummy gate 163 down to the top surface of the third sacrificial layer 107 by using the third sacrificial layer 107, the dummy capping film 161, and the gate spacer 117 as etch stop films.

Referring to FIG. 3C, the source/drain region 150 may be formed by epitaxial growth using the third sacrificial layer 107 as a seed. The first insulating layer 141 may be formed on the source/drain region 150. Through this process, the top surface of the source/drain region 150 of the semiconductor device 100 may have a round shape later.

Referring to FIG. 3D, the dummy capping film 161 and the dummy gate 163 may be etched (E1) down to a vertical level at which the source/drain region 150 is in contact with the first insulating layer 141, e.g., so upper surfaces of the source/drain region 150 and a remainder of the dummy gate 163 may be coplanar. At this time, the first insulating layer 141 and the gate spacer 117 may be partially removed, e.g., the gate spacer 117 may extend above the upper surface of the source/drain region 150.

The second sacrificial layer 105 and the dummy gate 163 may be partially etched (E2). For example, as illustrated in FIG. 3C, a portion of the dummy gate 163 directly contacting the second sacrificial layer 105 may be removed to define an empty space between the remainder of the dummy gate 163 and the second sacrificial layer 105.

Referring to FIG. 3E, the gate electrode 111 may be formed on the inner side of the gate spacer 117 to be higher than the vertical level at which the source/drain region 150 is in contact with the first insulating layer 141, e.g., the gate electrode 111 may extend vertically above and below the source/drain region 150 to have a larger thickness in the Z-axis directions than the source/drain region 150. At this time, before the gate electrode 111 is formed, a gate dielectric film may be formed on the inner side of the gate spacer 117. The gate dielectric film may surround a region of the gate electrode 111 other than a region of the gate electrode 111 in contact with the first capping film 113 described below. Subsequently, the first capping film 113 may be formed on the inner side of the gate spacer 117 and on the gate electrode 111. The first capping film 113 may be formed up to the vertical level of the gate spacer 117 and the first insulating layer 141, e.g., so upper surfaces of the first capping film 113, the gate spacer 117, and the first insulating layer 141 may be coplanar.

Referring to FIG. 3F, the first insulating layer 141 may be stacked more in the vertical direction, e.g., the first insulating layer 141 may be additionally formed to extend above and over upper surfaces of the first capping film 113 and the gate spacer 117. Then, the back-side contact 125 may be formed in the first insulating layer 141. The back-side contact 125 may pass through the first insulating layer 141 and may partially pass through the bottom surface of the source/drain region 150, e.g., the back-side contact 125 may continuously extend through the first insulating layer 141 and into a portion of the source/drain region 150. Subsequently, the power line 121 and an additional insulating layer may be formed on the first insulating layer 141 and the back-side contact 125, e.g., so the power line 121 and the back-side contact 125 may be in direct contact with each other.

Referring to FIG. 3G, the resultant structure of FIG. 3F may be turned upside down and bonded to a substrate. Thereafter, the first sacrificial layer 103 may be removed and the second sacrificial layer 105 may be selectively etched (E3) down to the top surface of the source/drain region 150, e.g., the second sacrificial layer 105 may be completely removed to expose the source/drain region 150 and the gate electrode 111 with the gate spacer 117 extending above the source/drain region 150.

Referring to FIG. 3H, a portion of a second insulating layer 143 may be formed on the source/drain region 150 by using vapor deposition. For example, as illustrated in FIG. 3H, upper surfaces of the gate electrode 111, the gate spacer 117, and second insulating layer 143 may be coplanar.

Referring to FIGS. 31 and 3J, an upper portion of the gate electrode 111 may be recessed (E4), such that the top surface of the gate electrode 111 is at a vertical level that is higher than or equal to the top surface of the source/drain region 150. For example, as illustrated in FIG. 3I, the gate spacer 117 may extend above the resultant recessed top surface of the gate electrode 111. Subsequently, the second capping film 115 may be formed on the resultant recessed top surface of the gate electrode 111, such that the upper surfaces of the second capping film 115 and the gate spacer 117 may be coplanar (FIG. 3J).

Referring back to FIG. 2, the second insulating layer 143 may be stacked more in the vertical direction and the front-side contact 135 and the front-side via 133 may be formed passing through the second insulating layer 143. Subsequently, the signal line 131, the front-side wiring insulating film 145, and the front-side wiring contact 137 may be sequentially formed, thereby manufacturing the semiconductor device 100.

As described above, the semiconductor device 100 may include the first capping film 113 on the bottom surface of the gate electrode 111 and the second capping film 115 on the top surface of the gate electrode 111, i.e., on opposite surfaces of the gate electrode 111 in the vertical direction. Accordingly, a contact (e.g., the front-side contact 135) extending from a front-side wiring structure and a contact (e.g., the back-side contact 125) extending from a back-side wiring structure may be connected to the source/drain region 150, e.g., contacts may be electrically connected to opposite surfaces (in the vertical direction) of adjacent source/drain regions 150. Through this structure, the contacts may be prevented from being misaligned with the gate electrode 111.

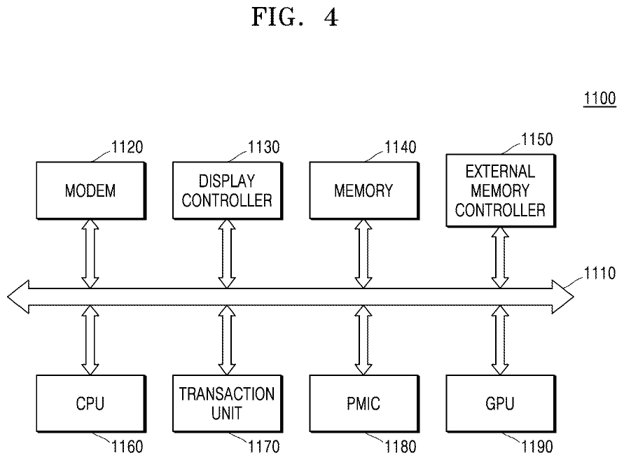

FIG. 4 is a block diagram of a system-on-chip (SoC) 1100 according to an embodiment. As a semiconductor apparatus, the SoC 1100 may include a semiconductor device according to an embodiment. The SoC 1100 may be obtained by implementing complex blocks, e.g., intellectual property (IP), performing various functions in a single chip. The SoC 1100 may be designed by a method of designing a semiconductor device, according to an example embodiment, and may thus have high performance and efficiency.

Referring to FIG. 4, the SoC 1100 may include a modem 1120, a display controller 1130, a memory 1140, an external memory controller 1150, a central processing unit (CPU) 1160, a transaction unit 1170, a power management integrated circuit (PMIC) 1180, and a graphics processing unit (GPU) 1190. The functional blocks of the SoC 1100 may communicate with one another through a system bus 1110.

The CPU 1160 may control the operation of the SoC 1100 at the top layer. The CPU 1160 may control operations of the other functional blocks, i.e., the modem 1120, the display controller 1130, the memory 1140, the external memory controller 1150, the transaction unit 1170, the PMIC 1180, and the GPU 1190. The modem 1120 may demodulate a signal received from the outside of the SoC 1100 or modulate a signal generated in the SoC 1100 and transmit the generated signal to the outside.

The external memory controller 1150 may control data communication with an external memory device connected to the SoC 1100. For example, a program and/or data may be provided from an external memory device to the CPU 1160 or the GPU 1190 under control by the external memory controller 1150. The GPU 1190 may execute program instructions related to graphics processing. The GPU 1190 may receive graphics data through the external memory controller 1150 and transmit graphics data, which has been processed by the GPU 1190, to the outside of the SoC 1100 through the external memory controller 1150.

The transaction unit 1170 may monitor a data transaction of each functional block. Under control by the transaction unit 1170, the PMIC 1180 may control power supplied to each functional block. The display controller 1130 may control a display (or a display device) outside the SoC 1100 such that data generated in the SoC 1100 may be transmitted to the display. The memory 1140 may include non-volatile memory, e.g., EEPROM or flash memory, or volatile memory, e.g., DRAM or SRAM.

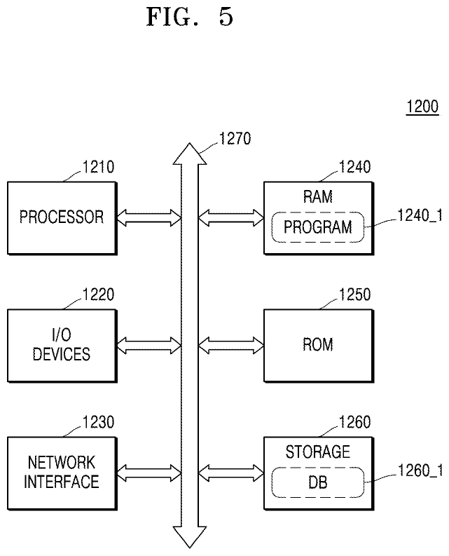

FIG. 5 is a block diagram of a computing system 1200 including memory storing a program of a semiconductor device, according to an embodiment. The computing system 1200 may include a stationary computing system, e.g., a desktop computer, a workstation, or a server, or a mobile computing system, e.g., a laptop computer.

Referring to FIG. 5, the computing system 1200 may include a processor 1210, input/output (I/O) devices 1220, a network interface 1230, RAM 1240, ROM 1250, and a storage 1260. The processor 1210, the I/O devices 1220, the network interface 1230, the RAM 1240, the ROM 1250, and the storage 1260 may be connected to a bus 1270 and communicate with one another through the bus 1270.

The processor 1210 may be referred to as a processing unit and may include at least one core, e.g., a microprocessor, an application processor (AP), a digital signal processor (DSP), or a GPU, which may execute an instruction set (e.g., Intel Architecture (IA)-32, 64-bit extension IA-32, x86-64, PowerPC, Sparc, MIPS, ARM, or IA-64). For example, the processor 1210 may access memory, i.e., the RAM 1240 or the ROM 1250, through the bus 1270 and execute instructions stored in the RAM 1240 or the ROM 1250.

The RAM 1240 may store a program 1240_1 for executing a method of designing a semiconductor device, according to an embodiment, or at least part of the program 1240_1. The program 1240_1 may enable the processor 1210 to perform at least some of the operations included in the method of designing a semiconductor device. In other words, the program 1240_1 may include a plurality of instructions executable by the processor 1210.

The storage 1260 may not lose data stored therein even when power supplied to the computing system 1200 is cut off. For example, the storage 1260 may include a non-volatile memory device or a storage medium, e.g., magnetic tape, an optical disk, or a magnetic disk. The storage 1260 may be detachable from the computing system 1200. The storage 1260 may store the program 1240_1, according to an embodiment. Before the program 1240_1 is executed by the processor 1210, the program 1240_1 or at least part of the program 1240_1 may be loaded from the storage 1260 to the RAM 1240. Alternatively, the storage 1260 may store a file written in a programming language. The program 1240_1, which is generated from the file by a compiler or the like, or at least part of the program 1240_1 may be loaded to the RAM 1240. As shown in FIG. 5, the storage 1260 may store a database (DB) 1260_1. The DB 1260_1 may include information necessary to design a semiconductor device.

The storage 1260 may store data to be processed by the processor 1210 or data that has been processed by the processor 1210. In other words, the processor 1210 may generate data by processing data stored in the storage 1260, according to the program 1240_1, and store the generated data in the storage 1260. For example, the storage 1260 may store RTL data, netlist data, and/or layout data.

The I/O devices 1220 may include an input device, e.g., a keyboard or a pointing device, and an output device, e.g., a display device or a printer. For example, through the I/O devices 1220, a user may trigger execution of the program 1240_1 by the processor 1210.

The network interface 1230 may provide access to a network outside the computing system 1200. For example, the network may include a plurality of computing systems and communication links. The communication links may include, e.g., wired links, optical links, wireless links, or other types of links.

By way of summation and review, embodiments provide a semiconductor device having a gate electrode structure including a plurality of capping films. That is, according to embodiments, a semiconductor device may include a plurality of gate structures, each having a capping film arranged on each of the top and bottom surfaces of a gate electrode and a gate spacer covering the capping film and the gate electrode, such that a front-side contact or a back-side contact may be exactly aligned with a source/drain region between the gate structures.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a front-side wiring structure connected to a signal line;
a back-side wiring structure below the front-side wiring structure, the back-side wiring structure being connected to a power line; and
gate structures between the front-side wiring structure and the back-side wiring structure, each of the gate structures including a gate electrode, a first capping film, a second capping film, and a gate spacer, the first capping film being on a bottom surface of the gate electrode, and the second capping film being on a top surface of the gate electrode.

2. The semiconductor device as claimed in claim 1, wherein the gate structures are spaced apart from each other in a first horizontal direction, a source/drain region being positioned between the gate structures.

3. The semiconductor device as claimed in claim 2, wherein:
the source/drain region includes a top surface facing the front-side wiring structure and a bottom surface facing the back-side wiring structure,
the top surface of the source/drain region has a round shape having a width decreasing toward the front-side wiring structure, and
the bottom surface of the source/drain region is flat.

4. The semiconductor device as claimed in claim 2, further comprising:
a first insulating layer filling a space between the back-side wiring structure and each of the source/drain region and the gate structures; and
a second insulating layer filling a space between the front-side wiring structure and each of the source/drain region and the gate structures.

5. The semiconductor device as claimed in claim 2, wherein:
the back-side wiring structure includes a back-side contact connected to the source/drain region, and
the front-side wiring structure includes a front-side contact and a front-side via connected to the source/drain region.

6. The semiconductor device as claimed in claim 5, wherein each of the back-side contact and the front-side contact has a tapered shape having a width decreasing toward the source/drain region.

7. The semiconductor device as claimed in claim 5, wherein each of the back-side contact and the front-side contact extends between the gate structures and is connected to the source/drain region.

8. The semiconductor device as claimed in claim 1, wherein:
the first capping film and the second capping film of each of the gate structures covers the top and bottom surfaces of the gate electrode, and
the gate spacer of each of the gate structures covers a sidewall of the first capping film, a sidewall of the second capping film, and a sidewall of the gate electrode.

9. The semiconductor device as claimed in claim 1, wherein a thickness of the first capping film in a vertical direction is greater than or equal to a thickness of the second capping film in the vertical direction.

10. The semiconductor device as claimed in claim 1, wherein:
one of the gate structures does not include the second capping film, and
a top surface of the gate electrode of the one of the gate structures is in contact with a gate contact.

11. A semiconductor device, comprising:
a front-side wiring structure connected to a signal line;
a back-side wiring structure below the front-side wiring structure, the back-side wiring structure being connected to a power line; and
an electronic element between the front-side wiring structure and the back-side wiring structure, the electronic element including gate structures separated from each other in a first horizontal direction and a source/drain region between the gate structures,
wherein each of the gate structures includes a gate electrode, a capping film, and a gate spacer, and
wherein the capping film includes a first capping film and a second capping film, the first capping film being on a bottom surface of the gate electrode, and the second capping film being on a top surface of the gate electrode.

12. The semiconductor device as claimed in claim 11, further comprising:
a first insulating layer filling a space between the back-side wiring structure and the electronic element; and
a second insulating layer filling a space between the front-side wiring structure and the electronic element, the first insulating layer including a same material as a material of the second insulating layer.

13. The semiconductor device as claimed in claim 11, wherein:
the source/drain region includes a top surface facing the front-side wiring structure and a bottom surface facing the back-side wiring structure,
the top surface of the source/drain region is round toward the front-side wiring structure,
the bottom surface of the source/drain region is flat, and
a vertical level of the top surface of the source/drain region is lower than or equal to a vertical level of the top surface of the gate electrode.

14. The semiconductor device as claimed in claim 11, wherein:
the back-side wiring structure includes a back-side contact connected to the electronic element,
the front-side wiring structure includes a front-side contact and a front-side via, each connected to the electronic element,
the back-side contact passes through a bottom surface of the source/drain region, and
the front-side contact passes through a top surface of the source/drain region.

15. The semiconductor device as claimed in claim 14, wherein:
the front-side contact is connected to the signal line of the front-side wiring structure through the front-side via, and
the back-side wiring structure is connected to the signal line.

16. The semiconductor device as claimed in claim 11, wherein the gate spacer is between the gate electrode and the source/drain region and conformally covers a sidewall of the capping film and a sidewall of the gate electrode.

17. A semiconductor device, comprising:
a front-side wiring structure connected to a signal line;
a back-side wiring structure below the front-side wiring structure, the back-side wiring structure being connected to a power line;
an electronic element between the front-side wiring structure and the back-side wiring structure, the electronic element including gate structures separated from each other in a first horizontal direction and a source/drain region between the gate structures;
a first insulating layer filling a space between the back-side wiring structure and the electronic element; and
a second insulating layer filling a space between the front-side wiring structure and the electronic element,
wherein:
the source/drain region includes a top surface facing the front-side wiring structure and a bottom surface facing the back-side wiring structure,
the top surface of the source/drain region is round toward the front-side wiring structure, the bottom surface of the source/drain region is flat, and each of the gate structures includes a gate electrode, a capping film, and a gate spacer,
the capping film includes a first capping film and a second capping film, the first capping film being on a bottom surface of the gate electrode, and the second capping film being on a top surface of the gate electrode, and
the gate spacer covers a sidewall of each of the gate electrode, the first capping film, and the second capping film.

18. The semiconductor device as claimed in claim 17, wherein:
the back-side wiring structure includes a back-side contact connected to the electronic element, the front-side wiring structure includes a front-side contact and a front-side via each connected to the electronic element,
a vertical level of the top surface of the source/drain region is lower than or equal to a vertical level of the top surface of the gate electrode,
the back-side contact passes through the bottom surface of the source/drain region, and
the front-side contact passes through the top surface of the source/drain region.

19. The semiconductor device as claimed in claim 18, wherein each of the back-side contact and the front-side contact has a tapered shape having a width decreasing toward the electronic element and extends between the plurality of gate structures.

20. The semiconductor device as claimed in claim 18, wherein:
the first capping film includes a same material as a material of the second capping film, and
a thickness of the first capping film in a vertical direction is greater than or equal to a thickness of the second capping film in the vertical direction.
